(19) United States
(12) Patent Application Publication
(10) Pub. No.: US 2009/0160060 A1
(43) Pub. Date: Jun. 25, 2009

(54) METHOD OF MANUFACTURING SEMICONDUCTOR DEVICE

(76) Inventor: Ji-Ho Hong, Hwaseong-si (KR)

Correspondence Address: SHERR & VAUGHN, PLLC, 620 HERNDON PARKWAY, SUITE 200, HERNDON, VA, 20170, US

(21) Appl. No.: 12/334,509

(22) Filed: Dec. 14, 2008

(30) Foreign Application Priority Data
Dec. 21, 2007 (KR) 10-2007-0135130

(51) Int. Cl. H01L 23/48; H01L 21/4763

(52) U.S. Cl. 257/762; 438/618; 257/E21.575; 257/E23.169

(57) ABSTRACT

Embodiments relate to a method of manufacturing a semiconductor device having a porous low-k dielectric layer. According to embodiments, a method may include forming an inter metal dielectric (IMD) layer on and/or over a semiconductor substrate, forming copper lines having a stepped structure in the IMD layer, forming a barrier insulating layer on and/or over upper surfaces of the copper lines and the IMD layer, exposing a portion of the upper surface of the IMD layer by photolithography and etching processes, and forming air cavities in the IMD layer using a wet etching process on and/or over the exposed portion of the upper surface of the IMD layer. According to embodiments, a value of the dielectric constant (k) of the IMD layer or the porous low-k dielectric layer may be close to that of a vacuum state.

The present application claims priority under 35 U.S.C. 119 to Korean Patent Application No. 10˜2007˜0135130 (filed on Dec. 21, 2007), which is hereby incorporated by reference in its entirety.

### BACKGROUND

A semiconductor device manufacturing process may be divided into a front end of the line (FEOL) step, in which transistors may be formed on and/or over a silicon substrate, and a back end of the line (BEOL) step, in which lines may be formed. A line forming technique may interconnect respective transistors of a semiconductor integrated circuit and may form channels, which may supply power and may transmit a signal in a circuit on and/or over a silicon substrate.

To enhance a performance of a semiconductor device, and to reduce an RC time constant delay of semiconductor lines, crosstalk, and power consumption, line materials having a low resistance and low-k insulating materials having a low dielectric constant may be used to form semiconductor lines.

FIGS. 1 and 2 are drawings respectively illustrating a related art method of manufacturing a semiconductor device having copper lines. Referring to FIGS. 1 and 2, a semiconductor device may include semiconductor substrate 10, barrier insulating layer 20, inter metal dielectric (IMD) layer 30 (or a porous low-k dielectric layer 60), metal barrier layer 40, and metal lines 50.

As an insulating material having a low k for forming IMD layer 30 of semiconductor lines, SiO₂ may be used at the initial stage, as shown in FIG. 1. Thereafter, fluorine doped SiO₂ may be used. Further, a low-k dielectric may be used.

A porous low-k dielectric layer 60 may be used, as shown in FIG. 2. To satisfy a k value of a dielectric at 22 nm technology node or below indicated by International Technology Roadmap for Semiconductors (ITRS), use of a porous low-k dielectric, which may have air cavities, may be important.

Although various methods of forming air cavities in a dielectric using chemical vapor deposition (CVD) or spin coating may be used, a low-k dielectric, for example with a dielectric constant (k) which may be close to ‘1’, may not yet be applied to a BEOL step.

### SUMMARY

Embodiments relate to a semiconductor technique, and to a method of manufacturing a semiconductor device having a porous low-k dielectric layer. Embodiments may relate to a method of manufacturing a semiconductor device.

Embodiments relate to a semiconductor device and a method of manufacturing a semiconductor device having a porous low-k dielectric layer, in which a dielectric constant (k) of a porous low-k dielectric layer to isolate metal lines from each other may be relatively low.

According to embodiments, a method of manufacturing a semiconductor device may include at least one of the following. Forming an inter metal dielectric (IMD) layer on and/or over a semiconductor substrate. Forming copper lines having a stepped structure in the IMD layer. Forming a barrier insulating layer on and/or over an entire upper surface of the copper lines and the IMD layer. Exposing a portion of the upper surface of the IMD layer by photolithography and etching processes. Forming air cavities in the IMD layer performing a wet etching process on and/or over the exposed portion of the upper surface of the IMD layer.

According to embodiments, a method of manufacturing a semiconductor device may include at least one of the following. Forming a porous low-k dielectric layer on and/or over a semiconductor substrate. Forming copper lines having a stepped structure in the porous low-k dielectric layer. Forming a barrier insulating layer on and/or over an entire upper surface of the copper lines and the porous low-k dielectric layer. Exposing a portion of the upper surface of the porous low-k dielectric layer by photolithography and etching processes. Increasing a number of air cavities in the porous low-k dielectric layer by performing a wet etching process on and/or over the exposed portion of the upper surface of the porous low-k dielectric layer.

### DRAWINGS

FIGS. 1 and 2 are views respectively illustrating related art methods of manufacturing a semiconductor device having copper lines.

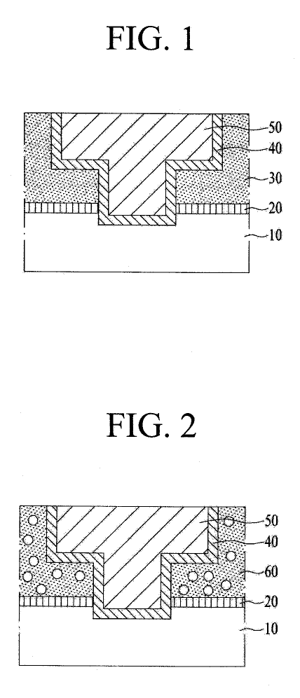

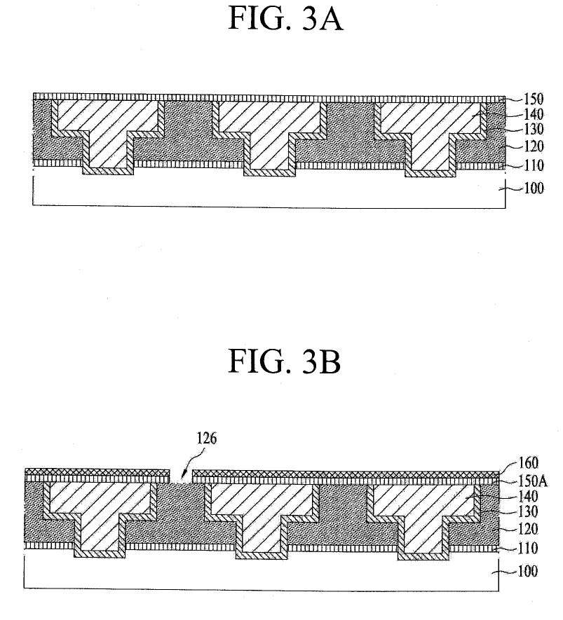

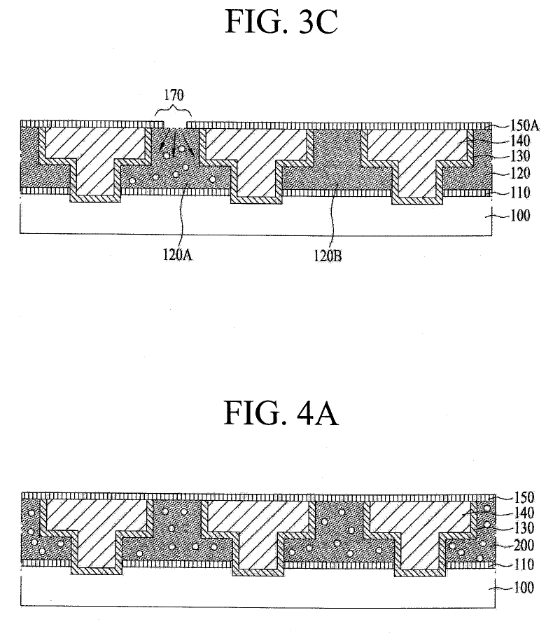

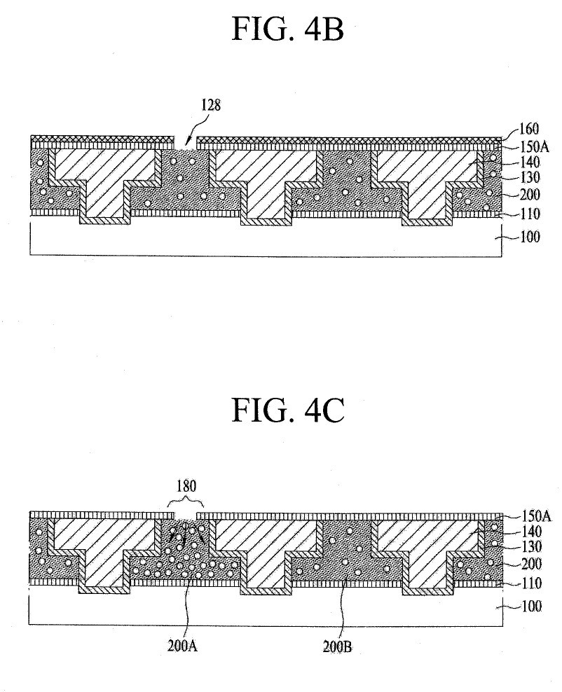

Example FIGS. 3A through 3C are longitudinal-sectional views illustrating a semiconductor device and a method of manufacturing a semiconductor device, according to embodiments.

Example FIGS. 4A through 4C are longitudinal-sectional views illustrating a semiconductor device and a method of manufacturing a semiconductor device, according to embodiments.

### DESCRIPTION

Embodiments relate to a semiconductor device and a process of manufacturing a semiconductor device that may have a porous low-k dielectric layer.

Example FIGS. 3A through 3C are longitudinal-sectional views illustrating a semiconductor device and a method of manufacturing a semiconductor device, according to embodiments. Referring to example FIG. 3A, inter metal dielectric (IMD) layer 120 may be formed on and/or over semiconductor substrate 100. According to embodiments, IMD layer 120 may be made of SiO₂. Barrier insulating layer 110 may be formed on and/or over semiconductor substrate 100 before IMD layer 120 may be formed. Lower metal lines may be formed on and/or over semiconductor substrate 100, and barrier insulating layer 110 may be formed on and/or over upper surfaces of the lower metal lines.

According to embodiments, copper lines 140, which may have a stepped structure, may be formed in IMD layer 120. According to embodiments, a damascene process may be used. This may allow copper lines 140 to have a stepped structure. Copper lines 140 may be formed using a damascene process, as follows.

According to embodiments, via holes and trenches may be formed through IMD layer 120 by photolithography and etching processes. Barrier insulating layer 110 may be used as an etch stopping layer in the photolithography and etching processes to form the via holes and trenches. After the via holes and trenches may be formed, metal barrier layer 130 may be formed on and/or over inner walls of the via holes and trenches. Metal barrier layer 130 may prevent copper of copper lines 140 from being diffused to IMD layer 120. According to embodiments, metal barrier layer 130 may be formed by depositing a material, such as TaN, Ta, TaN/Ta, TiSiN, WN, TiZrN, TiN, or Ti/TiN, in the via holes and trenches.

According to embodiments, insides of the via holes and trenches may be filled with copper, for example, using electrochemical plating. According to embodiments, it may be difficult to fill only an inside of the via holes and the trenches with copper. An excessive bulk of a copper layer may be relatively thickly formed on and/or over semiconductor substrate 100. The copper layer may be planarized up to a surface of IMD layer 120, for example by chemical mechanical polishing (CMP). Copper lines 140 may thus be formed.

According to embodiments, barrier insulating layer 150 may be formed on and/or over an upper surface of copper lines 140 and IMD layer 120. According to embodiments, barrier insulating layer 150 may be formed on and/or over an entire upper surface of copper lines 140 and IMD layer 120.

Referring to example FIG. 3B, portion 126 of an upper surface of IMD layer 120 may be exposed by photolithography and etching processes. According to embodiments, mask pattern 160, which may expose portion 126, may be formed on and/or over an upper surface of barrier insulating layer 150. According to embodiments, portion 126 of an upper surface of IMD layer 120 may be exposed by etching barrier insulating layer 150 using mask pattern 160. After portion 126 may be exposed, mask pattern 160 may be removed, for example by ashing.

Referring to example FIG. 3C, air cavities may be formed in portion 120A of IMD layer 120, for example by performing wet etching process 170 on and/or over exposed portion 126. According to embodiments, if wet etching process 170 is performed, a hydrogen fluoride (HF) solution may be permeated into IMD layer 120 through exposed inlet 126 (example FIG. 3B). This may isotropically wet-etch IMD layer 120. Compared with non-etched portion 120B of IMD layer 120, wet-etched portion 120A of IMD layer 120 may have air cavities formed therein. According to embodiments, IMD layer 120 may be converted into a porous low-k dielectric layer by wet etching process 170.

After the air cavities may be formed, a second IMD layer may be formed on and/or over an upper surface of etched barrier insulating layer 150A, for example by deposition. According to embodiments, exposed inlet 126 of IMD layer 120 may be covered with the second IMD layer.

Example FIGS. 4A through 4C are longitudinal-sectional views illustrating a semiconductor device and a method of manufacturing a semiconductor device, according to embodiments. Referring to example FIG. 4A, porous low-k dielectric layer 200 may be formed on and/or over semiconductor substrate 100. According to embodiments, barrier insulating layer 110 may be formed on and/or over semiconductor substrate 100 before porous low-k dielectric layer 200 may be formed. According to embodiments, lower metal lines may be formed on and/or over semiconductor substrate 100, and barrier insulating layer 110 may be formed on and/or over upper surfaces of the lower metal lines. Copper lines 140 may be formed in porous low-k dielectric layer 200, for example by a damascene process.

According to embodiments, via holes and trenches may be formed through porous low-k dielectric layer 200, for example by photolithography and etching processes. Barrier insulating layer 110 may be used as an etch stopping layer in the photolithography and etching processes used to form the via holes and trenches. After the via holes and trenches may be formed, metal barrier layer 130 may be formed on and/or over inner walls of the via holes and trenches. Metal barrier layer 130 may prevent copper of copper lines 140 from being diffused to porous low-k dielectric layer 200. According to embodiments, metal barrier layer 130 may be formed by depositing a material, such as TaN, Ta, TaN/Ta, TiSiN, WN, TiZrN, TiN, or Ti/TiN, in the via holes and the trenches.

According to embodiments, barrier insulating layer 150 may be formed on and/or over surfaces of copper lines 140 and porous low-k dielectric layer 200. According to embodiments, barrier insulating layer 150 may be formed on and/or over an entire upper surface of copper lines 140 and porous low-k dielectric layer 200.

Referring to example FIG. 4B, portion 128 of upper surface of porous low-k dielectric layer 200 may be exposed, for example by photolithography and etching processes. According to embodiments, mask pattern 160, which may expose portion 128, may be formed on and/or over an upper surface of barrier insulating layer 150. According to embodiments, portion 128 of an upper surface of porous low-k dielectric layer 200 may be exposed, for example by etching barrier insulating layer 150 using mask pattern 160. Mask pattern 160 may be removed by ashing after portion 128 may be exposed.

Referring to example FIG. 4C, a number of air cavities in portion 200A of porous low-k dielectric layer 200 may be increased by performing wet etching process 180 on and/or over exposed portion 128. According to embodiments, if wet etching process 180 is performed, a hydrogen fluoride (HF) solution may be permeated into porous low-k dielectric layer 200 through exposed inlet 128. This may isotropically wet-etch porous low-k dielectric layer 200. Compared with non-etched portion 200B of porous low-k dielectric layer 200, wet-etched portion 200A of porous low-k dielectric layer 200 may have a larger number of air cavities formed therein.

According to embodiments, after a number of the air cavities may be increased, a second porous low-k dielectric layer or an IMD layer may be formed on and/or over an upper surface of etched barrier insulating layer 150A, for example by deposition. According to embodiments, exposed inlet 128 of porous low-k dielectric layer 200 may be covered with the second porous low-k dielectric layer or the IMD layer.

According to embodiments, wet etching process 170 or 180, as shown in example FIG. 3C or 4C, may be performed using a hydrogen fluoride (HF) solution. According to embodiments, a concentration of an HF solution may be approximately 0.5˜10%. According to embodiments, an etch rate in wet etching process 170 or 180 may be determined by a kind of IMD layer 120 or porous low-k dielectric layer 200 and a concentration of an HF solution.

According to embodiments, if IMD layer 120 or porous low-k dielectric layer 200 is made of tetraethyl orthosilicate (TEOS) and a concentration of an HF solution is approximately 0.5˜1.5%, an etch rate in wet etching process 170 or 180 may be approximately 10˜15 nm per minute.

According to embodiments, if IMD layer 120 or porous low-k dielectric layer 200 is made of 1.5˜6.5% phosphor-silicate glass (PSG) and a concentration of an HF solution is approximately 0.5˜1.5%, an etch rate in wet etching process 170 or 180 may be approximately 5˜100 nm per minute.

According to embodiments, if IMD layer 120 or porous low-k dielectric layer 200 is made of 6.5˜15% phosphor-silicate glass (PSG) and a concentration of an HF solution is 0.5˜1.5%, an etch rate in wet etching process 170 or 180 may be approximately 5˜300 nm per minute.

According to embodiments, a buffered HF solution may be used to perform wet etching process 170 or 180 instead of an HF solution.

According to embodiments, in wet-etched porous low-k dielectric layer 200A, as shown in example FIG. 4C, a diffusion of air cavities may be promoted due to the air cavities, possessed by porous low-k dielectric layer 200 itself, when wet etching process 180 using an HF solution is performed. This may form a larger number of air cavities. According to embodiments, a number of the air cavities formed in wet-etched porous low-k dielectric layer 200A, manufactured according to embodiments and as illustrated in example FIG. 4C, may be larger than a number of the air cavities formed in wet-etched IMD layer 120A, manufactured according to embodiments and as illustrated in example FIG. 3C.

According to embodiments, in a method of manufacturing a semiconductor device having a porous low-k dielectric layer, an HF solution may be permeated into an IMD layer or a porous low-k dielectric layer. This may isolate metal lines from each other, and may cause a value of the dielectric constant (k) of an IMD layer or a porous low-k dielectric layer to be nearly close to ‘1’, which may be a vacuum state. It may also more efficiently separate the metal lines from each other. This may enhance a performance of a semiconductor device with respect to lines of a semiconductor device. It may also increase a yield of a semiconductor device.

According to embodiments, a method may be applied to semiconductor devices, such as a 0.11 nm-level logic device, a 90 nm-level logic device, a 90 nm-level stand-alone type flash memory, and 90 nm-level CMOS image sensor (CIS), and may enhance their yield.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method, comprising:
forming an inter metal dielectric (IMD) layer over a semiconductor substrate;
forming copper lines having a stepped structure in the IMD layer;
forming a barrier insulating layer over an upper surface of the copper lines and the IMD layer;
exposing a portion of the upper surface of the IMD layer by photolithography and etching processes; and
forming air cavities in the IMD layer by performing a wet etching process to the exposed portion of the upper surface of the IMD layer.

2. The method of claim 1, wherein the IMD layer comprises SiO₂.

3. The method of claim 1, wherein the copper lines having the stepped structure are formed in the IMD layer by performing a damascene process.

4. The method of claim 1, wherein a hydrogen fluoride (HF) solution is permeated into the exposed portion of the upper surface of the IMD layer by the wet etching process.

5. The method of claim 4, wherein a concentration of the HF solution is approximately 0.5˜10%.

6. The method of claim 4, wherein an etch rate of the wet etching process is determined by a material of the IMD layer and a concentration of the HF solution.

7. The method of claim 6, wherein the etch rate of the wet etching process is approximately 10˜5 nm per minute, when the IMD layer comprises TEOS and the concentration of the HF solution is approximately 0.5˜1.5%.

8. The method of claim 6, wherein the etch rate of the wet etching process is approximately 5˜100 nm per minute, when the IMD layer comprises 1.5˜6.5% PSG and the concentration of the HF solution is approximately 0.5˜1.5%.

9. The method of claim 6, wherein the etch rate of the wet etching process is approximately 5˜300 nm per minute, when the IMD layer comprises 6.5˜15% PSG and the concentration of the HF solution is approximately 0.5˜1.5%.

10. The method of claim 1, wherein the wet etching process is performed using a buffered hydrogen fluoride (HF) solution.

11. A method, comprising:
forming a porous low-k dielectric layer over a semiconductor substrate;
forming copper lines having a stepped structure in the porous low-k dielectric layer;
forming a barrier insulating layer over an upper surface of the copper lines and the porous low-k dielectric layer;
exposing a portion of the upper surface of the porous low-k dielectric layer by photolithography and etching processes; and
increasing a number of air cavities in the porous low-k dielectric layer by performing a wet etching process to the exposed portion of the upper surface of the porous low-k dielectric layer.

12. The method of claim 11, wherein the copper lines having the stepped structure are formed in the porous low-k dielectric layer by performing a damascene process.

13. The method of claim 11, wherein a hydrogen fluoride (HF) solution is permeated into the exposed portion of the upper surface of the porous low-k dielectric layer by the wet etching process.

14. The method of claim 13, wherein a concentration of the HF solution is approximately 0.5˜10%.

15. The method of claim 13, wherein an etch rate in the wet etching process is determined by a material of the porous low-k dielectric layer and the concentration of the HF solution.

16. The method of claim 15, wherein the etch rate of the wet etching process is approximately 10˜15 nm per minute, when the porous low-k dielectric layer comprises TEOS and the concentration of the HF solution is approximately 0.5˜1.5%.

17. The method of claim 15, wherein the etch rate of the wet etching process is approximately 5˜100 nm per minute, when the porous low-k dielectric layer comprises 1.5˜6.5% PSG and the concentration of the HF solution is approximately 0.5˜1.5%.

18. The method of claim 15, wherein the etch rate of the wet etching process is approximately 5˜300 nm per minute, when the porous low-k dielectric layer comprises 6.5˜15% PSG and the concentration of the HF solution is approximately 0.5˜1.5%.

19. The method of claim 11, wherein the wet etching process is performed using a buffered hydrogen fluoride (HF) solution.

20. A device, comprising:
an insulating layer having air cavities therein over a semiconductor substrate;
copper lines having a stepped structure in the insulating layer; and
a barrier insulating layer over an upper surface of the copper lines and the insulating layer,
wherein the insulting layer comprises one of a porous low-k dielectric layer and an inter metal dielectric (IMD) layer, and
wherein the air cavities are formed in the insulating layer by exposing a portion of the upper surface of the insulating layer by photolithography and etching processes, and forming the air cavities in the insulating layer by performing a wet etching process to the exposed portion of the upper surface of the insulating layer.
